(19) United States
(12) Patent Application Publication
(10) Pub. No.: US 2006/0160037 A1
(43) Pub. Date: Jul. 20, 2006

(54) AUTOMATED SUB-FIELD BLADING FOR LEVELING OPTIMIZATION IN LITHOGRAPHY EXPOSURE TOOL

(75) Inventors: Colin J. Brodsky, Salt Point, NY (US); Scott J. Bukofsky, Hopewell Junction, NY (US); Steven J. Holmes, Guilderland, NY (US)

Correspondence Address: DELIO & PETERSON, LLC, 121 WHITNEY AVENUE, NEW HAVEN, CT, 06510, US

(73) Assignee: INTERNATIONAL BUSINESS MACHINES CORPORATION, ARMONK, NY (US)

(21) Appl. No.: 10/905,706

(22) Filed: Jan. 18, 2005

(51) Int. Cl. G03F 7/20

(52) U.S. Cl. 430/396

(57) ABSTRACT

A method of exposing images on a wafer having varying topography during lithographic production of microelectronic devices. The method initially includes determining topography of a wafer, dividing the wafer into two or more separate regions based on the wafer topography, and determining desired focus distance for exposing a desired image on each of the separate regions of the wafer. The method then includes exposing a desired image on one of the regions of the wafer at the desired focus distance while blocking remaining regions and exposing a desired image on another of the regions of the wafer at the desired focus distance while blocking remaining regions. The desired focus distance may be different for each of the separate wafer regions.

### BACKGROUND OF THE INVENTION

1. Field of the Invention

This invention relates to lithographic production of microelectronic devices and, in particular, to the lithographic exposure tools utilized therein to expose circuit patterns and other images on the surface of the wafer used to produce the microelectronic device.

2. Description of Related Art

Lithographic processing generally involves exposing a desired pattern onto a resist layer on a wafer substrate layer using a step-and-scan exposure tool, developing the resist layer to remove the portions exposed (or not exposed), and then further processing the wafer, for example, by etching the underlying layer or depositing additional material, using the developed resist layer. Lithographic imaging is highly dependent on substrate uniformity to create an accurate circuit pattern on the surface of an individual wafer layer to be lithographically processed. A lithographic process can tolerate a small range of topography through the depth of focus (DOF) inherent in the process capability. DOF describes the ability of the lithographic imaging process to maintain image integrity over a range of focal planes. Unanticipated topography variation on the substrate has become a significant problem for many next generation lithography processes using high numerical aperture (NA) imaging. The trend of increasing NA allows increased resolution but this comes at the expense of process DOF.

Modern step-and-scan exposure systems utilize an optical leveling system that maps out topography across the wafer prior to exposure. A series of optical sensors across the exposure slit collect a grid of height data that effectively create a topographical map of the wafer prior to exposure. For example, in IBM's ASML Twinscan exposure tools, a band of seven measurement spots scans each die to build a complete topographic map of the wafer.

This topographic map is then used to control the height (focus) of the scanning slit above the wafer. Ideally, the height offset is held perfectly constant throughout the exposure to ensure that the lithographic image remains in focus. At any point during the exposure, a very narrow slice of a die is being exposed as the reticle and wafer move relative to each other, projecting the lithographic image through a lens in this slit. The exposure tool can adjust to fluctuations in step-height, using the previously obtained topographic map, by a set of simple linear motions. For changes in the height of the wafer in the direction of the scanning slit, the exposure tool can simply raise or lower the wafer stage as needed to compensate and maintain focus position while the slit moves across the die.

In the case where the pre-scan detects significant changes in step height across the exposure slit, there is limited ability to compensate. Since image focus cannot be varied across the slit, the tool must attempt to balance out this error using linear wafer stage movements. For example, the simplest adjustment is to pick a stage position that compromises the height between the two surfaces. This is known as a Z-position adjustment. Additionally, the tool may choose to tilt the wafer stage relative to the exposure slit. This is in fact the limit of today's exposure tools. In doing so, the total error is further minimized, but is clearly not driven to zero. In fact, with significant step heights, many areas across this slit still see significant deviation from best focus. When the process does not have adequate DOF to support these deviations, failures are seen at these points, and this in fact happens frequently on early test sites.

The root cause of the topography variation leading to this is often pattern-density driven. In many cases, the pattern density in the test kerf is quite different than the product chips. Beyond this, product chips may also vary in density. As mask set costs escalate, it is increasingly common for customers to share these costs by coordinating a variety of different chips onto one reticle, sometimes even coordinating with other customers. Since these chips may have quite different design purposes, there is further opportunity for non-uniform pattern density. These pattern density offsets can eventually lead to a step height due to film coating and chemical-mechanical polishing (CMP) over the differing densities. As the wafers process through many successive deposition steps, small differences may eventually become amplified towards latter processing stages where they are often observed to cause product failures.

Such errors are difficult to predict, identify, and correct. Identification of missing patterns attributable to focus errors in many of these levels can be challenging. In many cases, critical failures are not found with conventional inline inspection techniques. Traditional fixes include improving the overall process latitude (often not feasible if step heights are excessive), improving the CMP uniformity, or scrapping the reticle set and re-designing in a way that better balances pattern density. All of these are both costly and time consuming, and in some cases, a practical solution cannot be found.

### SUMMARY OF THE INVENTION

Bearing in mind the problems and deficiencies of the prior art, it is therefore an object of the present invention to provide a system and method for improving lithographic exposure of circuit patterns and other images in the manufacture of microelectronic devices.

It is another object of the present invention to provide a system and method for accurately exposing a circuit patterns or other image on varying topography of a wafer used in the manufacture of microelectronic devices.

A further object of the invention is to provide a system and method for compensating for significant differences in height of a wafer on which a circuit patterns or other image is to be exposed.

It is yet another object of the present invention to provide a system and method for optimizing focus on each portion of a wafer used in the manufacture of microelectronic devices.

Still other objects and advantages of the invention will in part be obvious and will in part be apparent from the specification.

The above and other objects, which will be apparent to those skilled in art, are achieved in the present invention which is directed to a method of exposing a substrate in a lithographic process comprising scanning the substrate to determine topography of the substrate and dividing the substrate into at least two designated areas based on the substrate topography. The method then separately exposes the designated areas by blocking a designated area while scanning an unblocked designated area, with the separate exposures being performed at different focus positions relative to the substrate.

Preferably, the substrate is scanned to determine topography in a first direction over the substrate, and the substrate is exposed in a second direction normal to the first direction. The designated areas may be exposed by, in sequence, blocking a first designated area, exposing a second designate area, blocking the second designated area and exposing the first designated area. The separate exposures may be performed at different, constant focus positions relative to the substrate. The substrate may be divided into more than two designated areas based on the substrate topography, such that the separate exposures are performed at more than two different focus positions relative to the substrate.

The different designated areas on the substrate may define different final product chips. Also, a least one designated area on the substrate may define a test pattern.

The substrate may be scanned to determine topography with the exposure tool, and the exposure may be performed by the exposure tool as it passes over the entire substrate during each designated area exposure. The exposure tool may travel in a first direction over the substrate during topography scanning, and in a second direction normal to the first direction during the designated area exposures.

In another aspect, the present invention provides a method of exposing images on a wafer having varying topography during lithographic production of microelectronic devices by determining topography of a wafer, dividing the wafer into two or more separate regions based on the wafer topography, and determining desired focus distance for exposing a desired image on each of the separate regions of the wafer. The method then includes exposing a desired image on one of the regions of the wafer at the desired focus distance while blocking remaining regions and exposing a desired image on another of the regions of the wafer at the desired focus distance while blocking remaining regions. The desired focus distance may be different for each of the separate wafer regions.

The method may include dividing the wafer into at least two separate regions across a first direction based on the wafer topography, and exposing the desired images on the separate wafer regions by scanning the images in a second direction normal to the first direction. The wafer regions may be exposed to the desired image by a scanner above the wafer, and during each exposure of the wafer regions the distance between the scanner and wafer may be changed. The method may further include determining optimum number of wafer regions to balance number of exposures with desired focus distances.

In yet another aspect, the present invention provides a method of exposing images on a wafer having varying topography during lithographic production of microelectronic devices comprising the steps of:

a) establishing a threshold of variation in topography for maintaining focus of an image to be exposed on a wafer;

b) determining variation in topography of the wafer;

c) comparing the wafer topography variation to the topography variation threshold;

d) if the wafer topography variation exceeds the topography variation threshold, dividing the wafer into at least two separate regions based on the wafer topography;

e) determining variation in topography of each separate region of the wafer;

f) comparing the wafer topography variation in each separate region to the topography variation threshold;

g) if the wafer topography variation exceeds the topography variation threshold in any region, dividing that region of the wafer into at least two additional separate regions based on the wafer topography;

h) optionally repeating steps (e)-(g) until variation in topography in all regions of the wafer is no greater than the topography variation threshold; and

i) exposing a desired image on each of the wafer regions at a desired focus distance.

The method preferably includes exposing a desired image on at least one of the regions of the wafer at the desired focus distance while blocking at least some remaining regions.

A further aspect of the present invention relates to a system for exposing images on a wafer having varying topography during lithographic production of microelectronic devices comprising a support for the wafer, sensors for determining topography of the wafer, and a computer program to determine division of the wafer into at least two separate regions based on the wafer topography. The system further includes a scanner above the wafer for exposing a desired image on the regions of the wafer at a desired focus distance from the wafer and a cover between the wafer and scanner for blocking remaining wafer regions while the scanner is exposing a desired image on one of the wafer regions. Preferably there is included a computer program to establish desired focus distance of the scanner from each of the wafer regions based only on the topography of each wafer region.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 is top plan view of a wafer showing the location of different test macro and chiplet pattern areas.

FIG. 2 is a graphical representation of the different step heights observed for the wafer of FIG. 1 in the Y-direction.

FIG. 3 is a top plan view showing the initial partial exposure of the wafer of FIG. 1 in accordance with the present invention.

FIG. 4 is a top plan view showing the subsequent partial exposure of the wafer of FIG. 1 in accordance with the present invention.

FIG. 5 is a flow chart showing the preferred method of the present invention.

FIG. 6 is a graphical representation of the different step heights observed for another wafer in the Y-direction.

### DESCRIPTION OF THE PREFERRED EMBODIMENT(S)

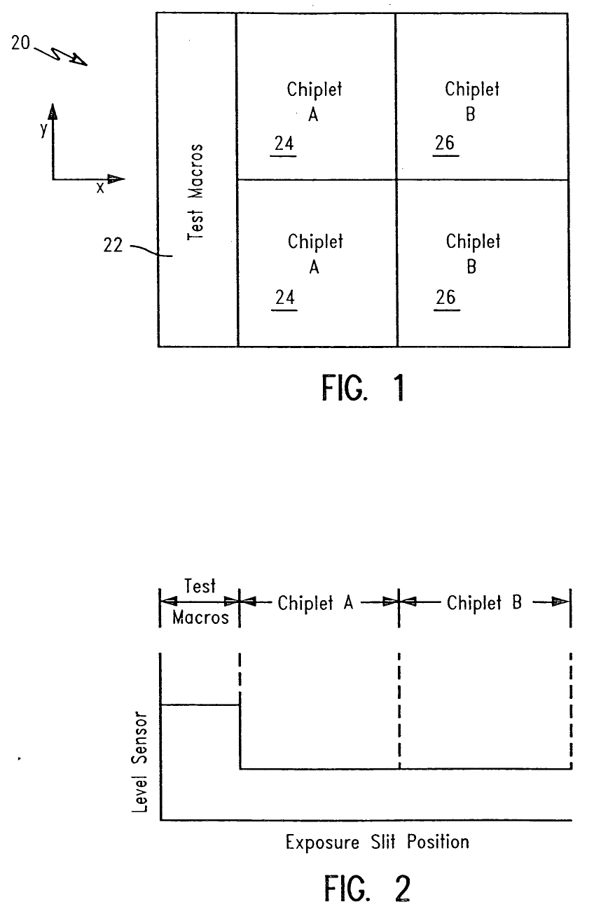

In describing the preferred embodiment of the present invention, reference will be made herein to FIGS. 1-6 of the drawings in which like numerals refer to like features of the invention.

The present invention divides or fractures portions of the wafer, also know as chiplets, into different scanning regions based on topographical data, and then incorporates potential chiplet fracturing in the reticle design and provides the exposure system with detailed information regarding these potential fracture points. With this information, the exposure tool can monitor and compensate the step height differences induced by variations in different areas of the wafer, e.g., from one customer part to another, or between test macros and product chips. In cases where significant topography variation is detected and exceeds the predetermined process DOF, the method of the present invention breaks the die down based on the predetermined fracture points and uses the exposure tool scanner to expose each chiplet separately at an optimal focus condition for that particular chiplet. Although this fracturing process may slow tool throughput, it is preferably utilized only on an as-needed basis by comparing the pre-mapped topography in each die against the process depth of focus. Through this methodology, the tool can intelligently balance tool throughput versus yield.

The step heights caused by pattern density or any other source may be detected by a prescreening method in the exposure tool as described above. Alternatively, any other suitable measurement technique may be used to gain this information prior to exposure such as AFM mapping of the wafer or independent optical surface mapping tools.

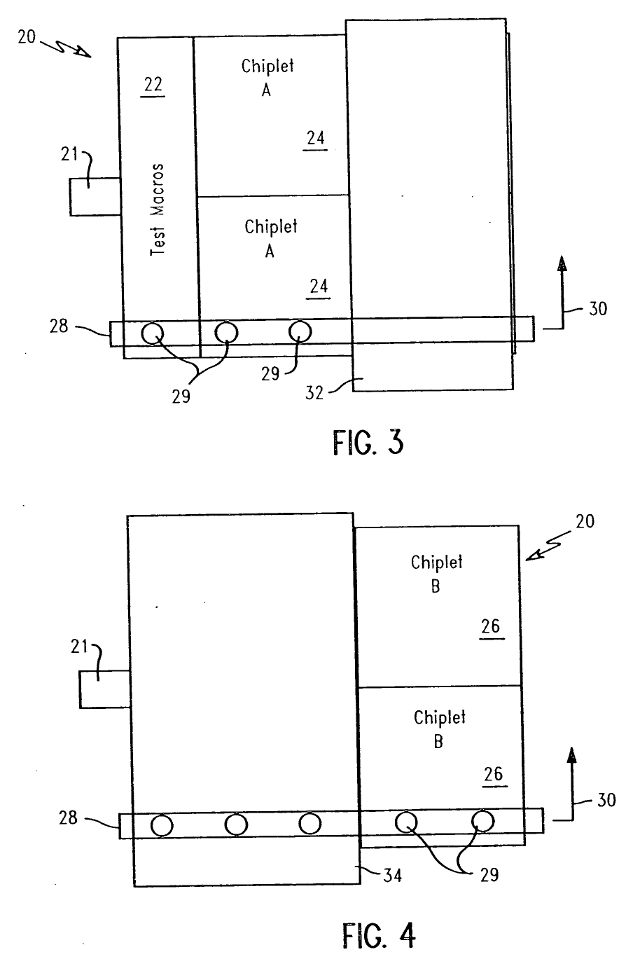

FIG. 1 depicts a portion of a wafer or chip 20 fractured or divided into different regions onto which different images of circuit or other patterns are to be exposed. These areas are test macro region 22, identical chiplet A areas 24, and identical chiplet B areas 26 separated across the X-direction of the wafer. In an example based on the wafer shown in FIG. 1, a topographic pre-scan in the Y-direction has determined that the test macros 22 and chiplets A 24 lie at a different height than chiplets B 26, as shown in FIG. 2. This pre-scan may be accomplished by optical sensors 29 mounted across exposure slit 28 of a step-and-scan exposure system, as shown in FIGS. 3 and 4. In accordance with the method of the present invention, the lithographic exposure tool first runs an exposure pass in the Y-direction (normal to the X-direction of separation) at one focus position for a first portion of the wafer, the test macros 22 and product chiplets A 24, while blocking off the remaining wafer portions, product chiplets B 26.

FIG. 3 shows a wafer 20 supported by an underlying wafer holder 21, over which a scanner 28 is supported at a variable distance from the wafer surface. As depicted therein, scanning slit 28 passes over wafer 20 in Y-direction 30, and the wafer is fractured to only expose test macros 22 and product chiplets A 24 to the desired circuit or other image, while chiplets B are blocked by cover 32. During this pass the scanner height and focus with respect to the wafer is set with regard only to the leveling topographical data collected for test macros 22 and product chiplets A 24, and without regard for the data collected for chiplets B. This is followed by a second pass in the same direction, but at a new focus position, where the tool blocks off the previously exposed test macros and chiplets. The subsequent scanning exposure pass is shown in FIG. 4 where test macros 22 and product chiplet A 24 are blocked by cover 34, while chiplets B 26 are exposed to the image scanned in direction 30. During this subsequent pass, the scanner height and focus with respect to the wafer is set with regard only to the leveling topographical data collected for chiplets B 26, and without regard for the data collected for the test macros and product chiplets A. By so fracturing the exposures, the distance between the scanner and wafer surface, i.e., the focus, is optimized for each portion of the overall wafer or chip, based on the previously acquired topographical map of the chip.

The present invention may be used to separately scan either full individual chiplet or test macro areas on the wafer, or portions or increments thereof. In the case of the latter, for alignment purposes, preferably one should make the separate exposure passes on increments of full chiplets or test macro regions that are specifically designed for use with the present invention. It is difficult to expose part of a chiplet at one level setting in one pass and follow with the other half of the same chiplet at a different level setting if microscale circuit continuity is to be maintained across the chiplet. Therefore, a further aspect of the method of the present invention is teaching the tool how the reticle creating the image is configured, so that the exposure tool understands what degrees of freedom it has to optimize the exposure passes. Specifically, each area that is a candidate for fracturing preferably incorporates alignment marks and overlay marks to evaluate overlay performance from the various passes. The layout for both complete chiplets is defined, along with additional definitions for sub-chiplets that may optionally be fractured. For example, exposure layer “AA” may be defined conventionally for the full chiplet. Then, exposure layers AA.1, AA.2, AA.x would define the boundaries of fracturable chiplets within layer AA.

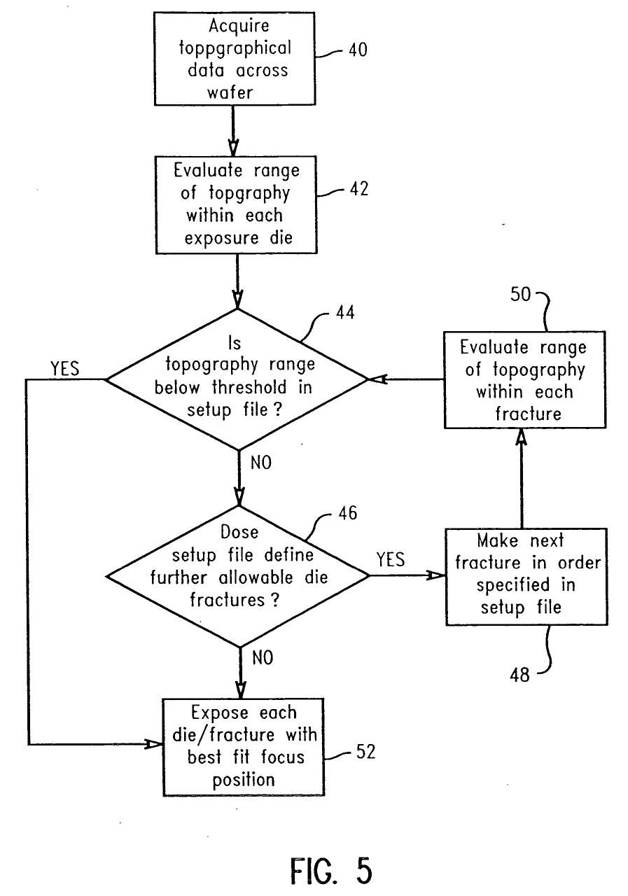

Since exposure pass separation can slow down wafer throughput at the scanner, it is preferable that the layout of the chiplets, test macros, and other portions of the wafer within the overall chip be understood, so that an evaluation can be made on a per wafer or per lot basis to determine whether multiple exposure passes are necessary to ensure good process yield. By taking measurements just prior to exposure, in conjunction with engineering input for the depth of focus or other relevant process capability parameters for each exposure operation, the method of the present invention provides for intelligent evaluation to optimize the throughput-yield tradeoffs. For example, a process depth of focus (DOF) is typically measured in lithography. This parameter is a measure of how much focus plane variation may be tolerated while keeping the projected image within specifications. A target threshold may be established in the recipe setup file based on this DOF or some fraction thereof such that if the wafer surface variation exceeds this parameter, exposure pass fracturing is performed. This is illustrated in the flowchart shown in FIG. 5, where in step 40 there is acquired topographical data across the wafer, and in subsequent step 42 the range of topography within each established exposure die or wafer portion is evaluated. If in the next step 44 the topography range is below the DOF threshold in the setup file, each established die or fracture (wafer portion) is sequentially exposed with the best fit focus position, while the remaining die/fracture is blocked in step 52. If the topography range exceeds the DOF threshold in the setup file, step 46 determines whether the setup file defines further allowable die fractures. Specifically, the file checks the current exposure fragment to see if additional sub-field fracturing options were defined in the recipe setup. If not, the process proceeds to step 52. If the setup file does define further allowable die fractures, in step 48 the next fracture of the wafer is made in the order specified in the setup file, and in step 50 the range of topography is evaluated within each fracture. The process then moves back to step 44 and proceeds as described above.

The method of the present invention of exposing images on a wafer having varying topography during lithographic production of microelectronic devices may be implemented by a computer program or software incorporating the process steps and instructions described above in otherwise conventional program code and stored on a lithographic step-and-scan exposure tool or otherwise conventional program storage device. The program code as well as the topographical data may be stored in the tool computer on a program storage device, such as a semiconductor chip, a read-only memory, magnetic media such as a diskette or computer hard drive, or optical media such as a CD or DVD ROM. The tool's computer system includes a microprocessor for reading and executing the stored program code in the manner described above to receive the wafer topographical data, determine division of the wafer into at least two separate regions based on the wafer topography, and then establish the desired optimum focus height or distance of the scanner above each of the wafer regions.

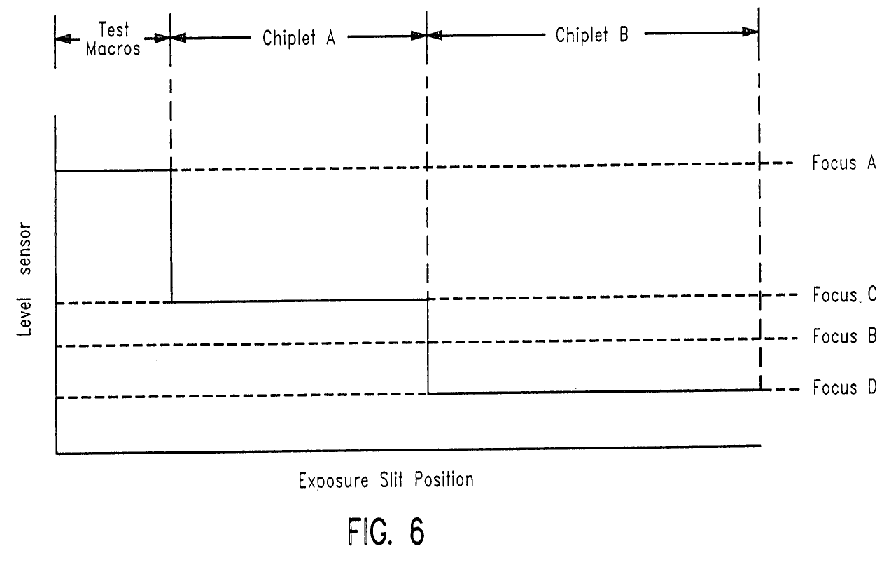

As indicated in the flow chart of FIG. 5, multiple fractures may be needed in some cases. This is illustrated in FIG. 6, where the topographical scan of wafer 20 in the Y-direction (FIG. 1) yields the heights shown in the graph corresponding to the test macros and product chiplets A and B separated along the X-direction. Under some circumstances, the process DOF can accommodate and absorb the planarity offset or difference between chiplets A and B, but not between the test macros and the product chiplets. In this case, the test macros are exposed during scanning in the Y-direction at focus height A, while chiplets A and B are blocked, and separately chiplets A and B are exposed during scanning in the Y-direction at focus height B, while the test macros are blocked.

If the process DOF cannot absorb the planarity offset between chiplets A and B, or between the test macros and the chiplet A, the wafer is fractured or divided three ways, between the test macros, chiplet A and chiplet B. In this case, the test macros are exposed during the scanning at focus height A, while chiplets A and B are blocked. Separately, chiplets A are exposed during the scanning at focus height C, while the test macros and chiplets B are blocked, and chiplets B are exposed during the scanning at focus height D, while the test macros and chiplets A are blocked. Each of the test macros, chiplets A and chiplets B are exposed by the scanner at their respective best focus height values in a total of three passes per wafer or die.

Thus, the present invention provides a system and method for accurately exposing a circuit patterns or other image on varying topography of a wafer used in the manufacture of microelectronic devices which compensates for significant differences in height of a wafer on which a circuit patterns or other image is to be exposed, and optimizes focus on each portion of a wafer.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

Thus, having described the invention, what is claimed is:

What is claimed is:

1. A method of exposing a substrate in a lithographic process comprising:
scanning the substrate to determine topography of the substrate;
dividing the substrate into at least two designated areas based on the substrate topography; and
separately exposing the designated areas by blocking a designated area while scanning an unblocked designated area, the separate exposures being performed at different focus positions relative to the substrate.

2. The method of claim 1 wherein the substrate is scanned to determine topography in a first direction over the substrate, and wherein the substrate is exposed in a second direction normal to the first direction.

3. The method of claim 1 wherein the designated areas are exposed by, in sequence, blocking a first designated area, exposing a second designate a area, blocking the second designated area and exposing the first designated area.

4. The method of claim 1 wherein the separate exposures are performed at different, constant focus positions relative to the substrate.

5. The method of claim 1 wherein the substrate is divided into more than two designated areas based on the substrate topography, such that the separate exposures are performed at more than two different focus positions relative to the substrate.

6. The method of claim 1 wherein the different designated areas on the substrate define different final product chips.

7. The method of claim 1 wherein at least one designated area on the substrate defines a test pattern.

8. The method of claim 1 wherein the exposure is performed by an exposure tool that passes over the entire substrate during each designated area exposure.

9. The method of claim 8 wherein the substrate is scanned to determine topography with the exposure tool.

10. The method of claim 1 wherein the exposure tool travels in a first direction over the substrate during topography scanning, and travels in a second direction normal to the first direction during the designated area exposures.

11. A method of exposing images on a wafer having varying topography during lithographic production of microelectronic devices comprising:
determining topography of a wafer;
dividing the wafer into at least two separate regions based on the wafer topography;
determining desired focus distance for exposing a desired image on each of the separate regions of the wafer;
exposing a desired image on one of the regions of the wafer at the desired focus distance while blocking remaining regions; and
exposing a desired image on another of the regions of the wafer at the desired focus distance while blocking remaining regions.

12. The method of claim 11 wherein the desired focus distance is different for each of the separate wafer regions.

13. The method of claim 11 including dividing the wafer into at least two separate regions across a first direction based on the wafer topography, and exposing the desired images on the separate wafer regions by scanning the images in a second direction normal to the first direction.

14. The method of claim 11 wherein the wafer is divided into more than two separate regions based on the wafer topography, and each region is separately exposed to the desired image while blocking remaining regions.

15. The method of claim 11 wherein the wafer regions are exposing to the desired image by a scanner above the wafer, and wherein during each exposure of the wafer regions distance between the scanner and wafer is changed.

16. The method of claim 11 further including determining optimum number of wafer regions to balance number of exposures with desired focus distances.

17. A method of exposing images on a wafer having varying topography during lithographic production of microelectronic devices comprising the steps of:
a) establishing a threshold of variation in topography for maintaining focus of an image to be exposed on a wafer;
b) determining variation in topography of the wafer;
c) comparing the wafer topography variation to the topography variation threshold;
d) if the wafer topography variation exceeds the topography variation threshold, dividing the wafer into at least two separate regions based on the wafer topography;
e) determining variation in topography of each separate region of the wafer;
f) comparing the wafer topography variation in each separate region to the topography variation threshold;
g) if the wafer topography variation exceeds the topography variation threshold in any region, dividing that region of the wafer into at least two additional separate regions based on the wafer topography;
h) optionally repeating steps (e)-(g) until variation in topography in all regions of the wafer is no greater than the topography variation threshold; and
i) exposing a desired image on each of the wafer regions at a desired focus distance.

18. The method of claim 17 including exposing a desired image on at least one of the regions of the wafer at the desired focus distance while blocking at least some remaining regions.

19. A system for exposing images on a wafer having varying topography during lithographic production of microelectronic devices comprising:
a support for the wafer;
sensors for determining topography of the wafer;
a computer program to determine division of the wafer into at least two separate regions based on the wafer topography;
a scanner above the wafer for exposing a desired image on the regions of the wafer at a desired focus distance from the wafer; and
a cover between the wafer and scanner for blocking remaining wafer regions while the scanner is exposing a desired image on one of the wafer regions.

20. The method of claim 17 including a computer program to establish desired focus distance of the scanner from each of the wafer regions based only on the topography of each wafer region.
